(19) United States
(12) Patent Application Publication
(10) Pub. No.: US 2026/0362989 A1
(43) Pub. Date: Nov. 12, 2026

(54) WURTZITE FERROELECTRIC NANOSTRUCTURES

(71) Applicant: The Regents of the University of Michigan, Ann Arbor, MI (US)

(72) Inventors: Ding Wang, Ann Arbor, MI (US); Ping Wang, Ann Arbor, MI (US); Zetian Mi, Ann Arbor, MI (US)

(21) Appl. No.: 19/515,341

(22) PCT Filed: Sep. 3, 2024
(86) PCT No.: PCT/US2024/044980

§ 371 Date: Feb. 27, 2026

Related U.S. Application Data
(60) Provisional application No. 63/536,257, filed on Sep. 1, 2023.

(51) Int. Cl. H10N 70/20; H10N 70/00

(52) U.S. Cl. CPC H10N 70/24; H10N 70/026; H10N 70/041; H10N 70/826; H10N 70/883

(57) ABSTRACT

A device includes a substrate and a nanostructure supported by the substrate. The nanostructure includes a template segment supported by the substrate, the template segment including a nitride semiconductor material, and a ferroelectric segment supported by the template segment, the ferroelectric segment including a nitride alloy. The ferroelectric segment has a sub-micron lateral dimension.

### CROSS-REFERENCE TO RELATED APPLICATION

This application claims the benefit of U.S. provisional application entitled “Wurtzite Ferroelectric Nanostructures,” filed Sep. 1, 2023, and assigned Ser. No. 63/536,257, the entire disclosure of which is hereby expressly incorporated by reference.

### STATEMENT REGARDING FEDERALLY SPONSORED RESEARCH OR DEVELOPMENT

This invention was made with government support under Contract No. 2235377 awarded by the National Science Foundation. The government has certain rights in the invention.

### BACKGROUND OF THE DISCLOSURE

### Field of the Disclosure

The disclosure relates generally to Group III-nitride materials.

### Brief Description of Related Technology

Conventional III-nitride semiconductors have been transformed to exhibit ferroelectric behavior with widely tunable properties by alloying with rare-earth elements such as scandium, boron and yttrium. Theoretical predictions suggest that ScAlN can maintain a wurtzite phase structure for Sc compositions up to 56%, with an energy bandgap that varies from about 6.2 eV to about 4 eV. The piezoelectric coefficient, permittivity, and optical χ⁽²⁾ properties have been dramatically enhanced with increasing Sc incorporation in ScAlN, accompanied by a significant reduction of the coercive field.

To date, however, achieving high-quality wurtzite ferroelectric semiconductors has remained a formidable challenge especially for high Sc contents, at which nonessential secondary phases are present. To avoid the formation of the secondary rock-salt phase, various growth approaches, including N-rich growth condition, metal-modulated epitaxy, and Ga-assisted epitaxy have been commonly adopted. To date, the achievement of reasonable quality wurtzite ScAlN has been often limited to Sc composition less than 40%.

### SUMMARY OF THE DISCLOSURE

In accordance with one aspect of the disclosure, a device includes a substrate and a nanostructure supported by the substrate. The nanostructure includes a template segment supported by the substrate, the template segment including a nitride semiconductor material, and a ferroelectric segment supported by the template segment, the ferroelectric segment including a nitride alloy. The ferroelectric segment has a sub-micron lateral dimension.

In accordance with another aspect of the disclosure, a device includes a substrate and a nanostructure supported by the substrate. The nanostructure includes a template segment supported by the substrate, the template segment including a III-nitride semiconductor material, and a dielectric segment supported by the template segment, the dielectric segment including a III-nitride alloy, the III-nitride alloy including a Group IIIB element. The III-nitride alloy has a wurtzite crystal structure.

In accordance with yet another aspect of the disclosure, a method for fabricating a device includes providing a substrate, implementing a first growth procedure to grow a template nanostructure supported by the substrate, the template segment including a nitride semiconductor material, and implementing a second growth procedure to grow a ferroelectric nanostructure supported by the template nanostructure. The first growth procedure and the second growth procedure are configured such that the template nanostructure has a sub-micron lateral dimension and the ferroelectric nanostructure has a sub-micron lateral dimension, respectively.

In accordance with still yet another aspect of the disclosure, a method for fabricating a device includes providing a substrate, implementing a first growth procedure to grow a template nanostructure supported by the substrate, the template segment including a III-nitride semiconductor material, and implementing a second growth procedure to grow a dielectric nanostructure supported by the template nanostructure, the dielectric nanostructure including a III-nitride alloy, the III-nitride alloy including a Group IIIB element. The second growth procedure is configured such that the III-nitride alloy has a wurtzite crystal structure.

In accordance with still yet another aspect of the disclosure, a device includes a substrate and a ferroelectric nanostructure supported by the substrate, the ferroelectric nanostructure including a nitride alloy. The ferroelectric nanostructure has a sub-micron lateral dimension.

In accordance with another aspect of the disclosure, a method for fabricating a device includes providing a substrate, and implementing a growth procedure to grow a ferroelectric nanostructure supported by the substrate. The growth procedure is configured such that the ferroelectric nanostructure has a sub-micron lateral dimension.

In connection with any one of the aforementioned aspects, the devices and/or methods described herein may alternatively or additionally include or involve any combination of one or more of the following aspects or features. The ferroelectric segment has a wurtzite crystal structure. The nitride alloy has a Group IIIB content of about 0.4 or higher. The nanostructure is configured as a nanowire. The sub-micron lateral dimension is on the order of tens of nanometers or less. The ferroelectric segment has a nanoscale lateral dimension. The ferroelectric segment has a larger lateral diameter than the template segment. The nanostructure further includes a shell disposed along sidewalls of the template segment, the shell including the nitride alloy. The ferroelectric segment is in contact with the template segment. The nanostructure is one of an array of nanostructures of the device, each nanostructure of the array of nanostructures projecting outward from the substrate. The nitride semiconductor material is a III-nitride semiconductor material. The nitride alloy is a III-nitride alloy. The nitride alloy includes a Group IIIB element. The III-nitride alloy has a Group IIIB content of about 0.4 or higher. The dielectric segment is ferroelectric. The dielectric segment has a sub-micron lateral dimension. The dielectric segment has a lateral dimension on the order of tens of nanometers or less. The dielectric segment has a larger lateral diameter than the template segment. The nanostructure further includes a shell disposed along sidewalls of the template segment, the shell including the III-nitride alloy. The dielectric segment is in contact with the template segment. Providing the substrate includes removing a native oxide layer while the substrate is disposed in a growth chamber in which the first and second growth procedures are implemented. The first growth procedure is configured to dope the nitride semiconductor material such that the template nanostructure is conductive. The second growth procedure is configured such that the nitride alloy has a Group IIIB content of about 0.4 or higher. The first growth procedure is configured such that the template nanostructure has a lateral dimension on the order of tens of nanometers or less. The first and second growth procedures are configured such that the ferroelectric nanostructure has a larger lateral diameter than the template nanostructure. The second growth procedure is configured such that a shell grows along sidewalls of the template nanostructure, the shell including the III-nitride alloy. The second growth procedure is configured such that the III-nitride alloy has a Group IIIB content of about 0.4 or higher. The first growth procedure is configured to dope the III-nitride semiconductor material such that the template nanostructure is conductive. The first growth procedure and the second growth procedure are configured such that the template nanostructure has a sub-micron lateral dimension and the dielectric nanostructure has a sub-micron lateral dimension, respectively.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts structural phase evolution from wurtzite to rock-salt (cubic) in ScAlN nanowires, including (a) schematic illustrations of the geometry and atomic structure of wurtzite and rock-salt phase ScAlN with varying Sc content, (b) cross-sectional SEM images of ScAlN nanowire ensembles grown on GaN nanowire templates on Si(111) substrates (the SEM image for ScN/GaN nanowires is 45° tilted to show the cubic structure), (c) XRD 2θ-ω scans for the nanowire samples shown in part (b), showing a gradual shift towards higher angle side for wurtzite phase ScAlN, while the diffraction peak shifts in the opposite direction for ScAlN nanowires with Sc content beyond 0.45-0.5, due the dominated rock-salt phase (the diffraction peak for Si at 28.4° is used for calibration).

FIG. 2 depicts structural evolution of wurtzite ScAlN nanowires with a Sc content of 0.4 in accordance with one example, including (a) a HAADF-STEM image of a single ScAlN/GaN nanowire, showing GaN at the bottom and ScAlN grown on top with expanded diameter, (b) SAED patterns collected with a zone axis of [112̅0] from the GaN, ScAlN/GaN, and top ScAlN regions, respectively, confirming the dominated wurtzite structure for the entire nanowire, (c-d) high-resolution HAADF-STEM images recorded from (c) the ScAlN/GaN interface and (d) the center of ScAlN near the top surface (showing some nanometer sized cubic phase ScAlN domains enclosed with yellow dashed lines in part (c), and that the top ScAlN region exhibits a multi-domain structure with sharp vertical domain boundaries without compromising the wurtzite structure).

FIG. 3 depicts structural evolution of wurtzite ScAlN nanowires with a Sc content of 0.5 in accordance with one example, including (a) a HAADF-STEM image of a single ScAlN/GaN nanowire, (b) SAED patterns collected with a zone axis of [112̅0] from the GaN, ScAlN/GaN, and top ScAlN regions, respectively, exhibiting a dominant wurtzite structure at the interface region, with a polycrystalline structure for ScAlN far away from the interface, (c, d) high-resolution HAADF-STEM images recorded from (c) the ScAlN/GaN interface and (d) ScAlN near the top surface (showing some nanometer sized cubic phase ScAlN domains enclosed with yellow dashed lines in part (c), and that wurtzite and cubic mixed phases with varied orientation coexist in the top ScAlN region, giving rise to polycrystalline structure).

FIG. 4 depicts ferroelectric properties of ScAlN nanowires with a Sc content of about 0.33 in accordance with one example, including a) displacement currents and b) corresponding P-E loops after subtracting non-switching current using a PUND method, c) voltage-dependent PUND measurement results showing inclining polarization with increasing poling voltages, e) surface morphology, f) amplitude, and g) phase contrast of the ScAlN nanowires after poling at +150 V (upper panel) and −135 V (lower panel) and removing the top electrodes, in which white dashed curves are guidelines for the boundary of the electrode, and red circles indicate switched single nanowires.

FIG. 5 is a schematic view of a device having an array of nanostructures in accordance with one example.

FIG. 6 is a flow diagram of a method of fabricating a device having an array of nanostructures in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices having nanostructures capable of ferroelectric switching in reduced dimensions (e.g., nanoscale or other sub-micron lateral dimensions) are described. For example, the devices may include an array of one-dimensional nanostructures (e.g., nanowires), with each nanostructure of the array having a ferroelectric segment. The nanostructures of the disclosed devices also provide and support crystallographic phase control. For instance, the nanostructures of the disclosed devices remain wurtzite crystal structures at alloy composition levels higher than the level at which films and bulk structures transition to cubic phase. Methods for fabricating such devices are also described.

The exploration of crystallographic phase transition behavior, especially in low-dimensional forms is useful in realizing various devices and device properties. One such class of devices is ferroelectrics, which are useful in a variety of contexts, including power-efficient and highly integrated devices and systems.

The efficient strain relaxation and limited area epitaxy in low-dimensional nanostructures promotes the formation of dislocation-free, pristine heterostructures with tunable properties, as demonstrated recently for high efficiency nanowire green and red micro-LEDs. Therefore, understanding the crystallographic phase transition in the material with different Sc compositions, especially in low-dimensional forms, is useful in device development. While efforts have been taken to reducing the thickness of ScAlN films with promising results down to about 5 nm, the disclosed devices and methods pursue the lateral scaling down and size limit of wurtzite ferroelectrics, which is useful for power-efficient and highly-integrated device applications. While there have been previous reports on ScAlN based transistors with narrow channels or short gate lengths, such structures do not necessarily reflect the size of the switchable domains.

The disclosed devices and methods are described in connection with an investigation into the crystallographic phase transitions in ScAlN nanowires throughout the entire Sc spectrum. A distinct, gradual shift from the wurtzite to the cubic phase is observed as the Sc composition increased. The investigation further revealed that a well-ordered wurtzite phase ScAlN can be maintained at a ScAlN/GaN interface, even when the Sc concentration (e.g., 45-50%) far exceeds levels achievable in bulk layers (the levels of which are typically below 40%). This feature may be harnessed to confine and achieve high quality ferroelectric phase in a variety of device contexts.

The disclosed devices and methods achieve and enable ferroelectric switching in ScAlN nanowires of nanometer dimensions, an achievement with useful ramifications for the aggressive scaling of devices. For instance, the successful synthesis of pristine, tunable ScAlN nanowires is useful for the nanoscale, domain, alloy, and quantum control and engineering of ferroelectrics. This aspect of the disclosed devices and methods supports a variety of downsized devices leveraging wurtzite ferroelectrics.

The nanostructures of the disclosed devices are useful in a wide variety of device applications and contexts, including, for instance, electronics, acousto-electronics, and quantum photonics. The nanostructures may provide or support piezoelectric and/or ferroelectric properties, while being compatible with CMOS fabrication processes and capable of integration with other semiconductor fabrication technologies.

Described herein are examples of devices having highly ordered wurtzite phase ScAlN nanostructures confined at a ScAlN/GaN interface with Sc content levels surpassing that possible in conventional films. The disclosed devices exhibit ferroelectric switching in one-dimensional ScAlN nanowires, a feature useful for, among other things, device miniaturization. Tunable ferroelectric ScAlN nanowires may thus be realized, thereby supporting nanoscale, domain, alloy, strain, and quantum engineering of wurtzite ferroelectrics. A wide variety of miniaturized devices with wurtzite ferroelectrics may accordingly be realized.

Although described in connection with examples of epitaxially grown ScₓAl₁₋ₓN structures, the disclosed methods and devices may be applied to a wide variety of III-nitride alloys. The disclosed methods and devices may thus include or involve the incorporation of scandium into other III-nitride wurtzite structures. For instance, the disclosed methods and devices may include or involve one or more epitaxially grown ScₓAl_{y}Ga_{1-x-y}N structures, ScₓGa₁₋ₓN structures, or ScₓIn₁₋ₓN structures. The configuration, construction, fabrication, and other characteristics of the nanostructures may also vary from the examples described. For instance, the heterostructures may include any number of epitaxially grown segments of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although described in connection with examples having a template segment composed of GaN, the nanostructures of the disclosed devices may include alternative or additional III-nitride semiconductor segments as template, base, intermediate, or other segments. Additional or alternative types of materials may also be used in the nanostructures, including, for instance, other semiconductor materials. For instance, other nitride semiconductors, such as II-IV-Nitrides (e.g., ZnGeN₂, ZnSiN₂, ZnMgN₂, and related alloys), may be used as a template segment or nanostructure. In such cases, the composition of the dielectric (e.g., ferroelectric) segment or nanostructure may vary accordingly. Materials such as III-nitrides (without incorporating a IIIB element), e.g., AlN, AlBN, etc., may be used as a dielectric (e.g., ferroelectric) segment or nanostructure. Alternatively, materials based on the aforementioned II-VI nitrides may be used.

Although described in connection with examples having two segments, the nanostructures of the disclosed methods and devices may have more than two layers. For instance, the heterostructure may include one or more additional dielectric segments and/or one or more conductive segments.

Although the disclosed methods are described in connection with MBE growth procedures, additional or alternative non-sputtered epitaxial growth procedures may be used. For instance, metal-organic chemical vapor deposition (MOCVD), hydride vapor phase epitaxy (HVPE), atomic layer deposition (ALD), and atomic layer epitaxy (ALE) growth procedures may be used. Still other procedures may be used, including, for instance, pulsed laser deposition procedures.

The examples described below were grown using a Veeco GENxplor molecular beam epitaxy (MBE) system, equipped with Knudsen effusion cells for aluminum (Al, purity 99.99995%), gallium (Ga, purity 99.99999%), and scandium (Sc, purity 99.999%) sources, and a radio frequency (RF) plasma cell for nitrogen (N₂, purity 99.9999%) source. In these examples, the nanowire structures were grown directly on n-type Si wafers. The surface oxidation layer was removed by etching the Si wafers in buffered HF for 2 min prior to loading into the MBE system. Subsequently, the substrates were baked and outgassed at 200 °C and 600 °C for 2 h in the MBE load-lock and preparation chamber, respectively. After loading into the growth chamber, the Si substrates were further heated up to 900 °C to remove the native oxide. The growth temperature was calibrated by monitoring the (7×7) to (1×1) reconstruction transition of Si(111) at about 830 °C using an in-situ reflection high-energy electron diffraction (RHEED) system. Self-assembled GaN nanowires with a height of about 400 nm were first grown at 750 °C as the epitaxy template, followed by the growth of ScAlN segments with a nominal thickness of about 200 nm. The Ga beam equivalent pressure (BEP) was maintained at 1.0×10⁻⁷ Torr for the GaN nanowire growth, while the Sc (Al) BEP was varied from 0 to 3.0×10⁻⁸ Torr (3.0×10⁻⁸ to 0 Torr) to control the Sc content (from 0 to 1). The GaN segments were doped with Si at a dopant cell temperature of 1200 °C to serve as the bottom electrode for conducting ferroelectric characterization. Ti/Al electrodes were lithographically patterned after opening circular windows with diameters of 3-50 μm on 200-nm-thick SiO₂ deposited on the nanowire surface using a GSI ULTRADEP 2000 Plasma Enhanced Chemical Vapor Deposition (PECVD) system.

Further details on the epitaxial growth conditions, procedures, and related parameters that may be used to form the nanostructures described herein, including details regarding the growth of nanowires having one or more segments composed of III-nitride materials, are set forth in U.S. Pat. No. 8,563,395 (“Method of growing uniform semiconductor nanowires without foreign metal catalyst and devices thereof”), U.S. Pat. No. 9,112,085 (“High efficiency broadband semiconductor nanowire devices”), U.S. Pat. No. 9,240,516 (“High efficiency broadband semiconductor nanowire devices”), and Nguyen, et al., “p-Type Modulation Doped InGaN/GaN Dot-in-a-Wire White-Light-Emitting Diodes Monolithically Grown on Si(111),” Nano Lett 2011, 11 (5), 1919-1924, the entire disclosures of which are hereby incorporated by reference.

Further details on the epitaxial growth conditions, procedures, and related parameters that may be used to form the III-nitride alloy segments of the nanostructures described herein are set forth in WO 2023/022768 (“Epitaxial Nitride Ferroelectronics”), International Application No. PCT/US23/13727 (“Epitaxial Nitride Ferroelectronic Devices” filed Feb. 23, 2023), P. Wang, et al., “Fully epitaxial ferroelectric ScAlN grown by molecular beam epitaxy,” Applied Physics Letters, vol. 118, p. 223504 (2021), D. Wang et al., “An Epitaxial Ferroelectric ScAlN/GaN Heterostructure Memory,” Advanced Electronic Materials, p. 2200005 (2022), D. Wang, et al., “Fully epitaxial ferroelectric ScGaN grown on GaN by molecular beam epitaxy,” Appl Phys Lett 119 (11), 111902 (2021), D. Wang et al., “Impact of dislocation density on the ferroelectric properties of ScAlN grown by molecular beam epitaxy,” Appl Phys Lett 121 (4), 042108 (2022), and P. Wang et al., “Quaternary alloy ScAlGaN: A promising strategy to improve the quality of ScAlN,” Appl Phys Lett 120 (1), 012104 (2022), the entire disclosures of which are hereby incorporated by reference.

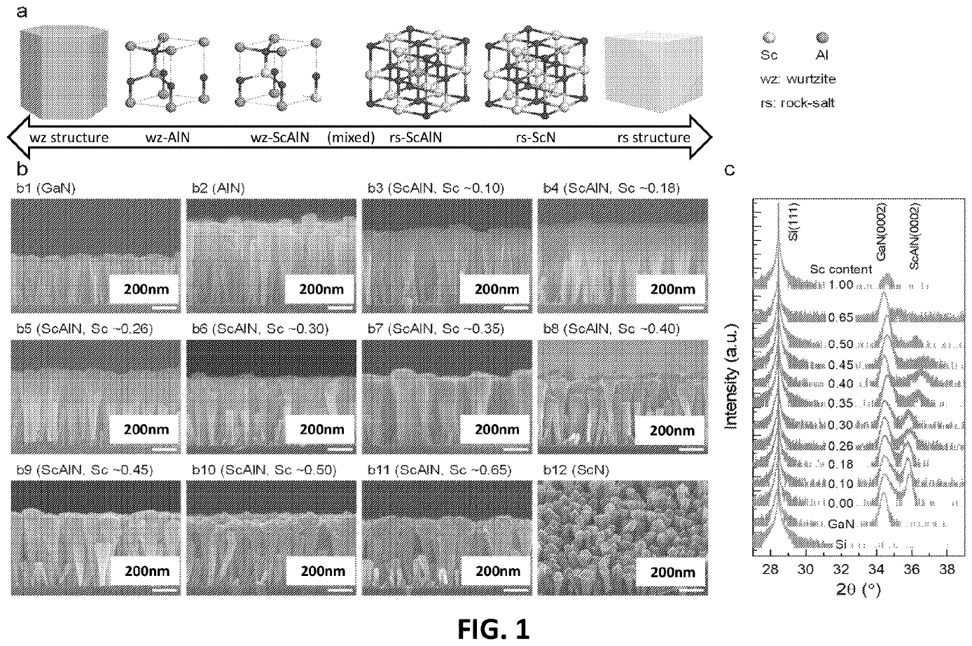

Schematically shown in FIG. 1, part a, III-nitride materials, such as AlN, have a wurtzite (wz) phase ground state, whereas ScN has a rock-salt (rs) phase ground state. This incompatibility leads to phase transition, lattice distortion, and material quality degeneration with increasing Sc content. To date, the effect of those evolution trends on domain structure and morphology have remained elusive, because all previous studies were focused on ScAlN films with limited tunability.

For nanowire growth, the crystal sites are separate, allowing each crystal phase to nucleate and grow via their most preferable crystallographic phase, thus providing a unique crystalline platform to visualize the transition process. FIG. 1, part b, shows the cross-sectional scanning electron microscope (SEM) images of ScAlN/GaN nanowires spontaneously grown on Si(111). The Sc content was determined using EDS equipped in the SEM system. By modulating the Sc/Al flux ratio, the Sc content was successfully tuned in the entire compositional range from 0 to 1. A clear evolution trend of the nanowire morphology is observed with increasing Sc contents as follows: (i) for a Sc content below 0.35, the ScAlN nanowires have a smooth sidewall, similar to conventional AlGaN nanowires, as shown in FIG. 1, parts b2-b7; (ii) for a moderate Sc content (0.4-0.5), ScAlN nanocrystals (with a size below 50 nm) start to grow on the sidewall, and the nanocrystal density increases with Sc content, while the nanowires are still dominated by vertical growth, as shown in FIG. 1, parts b8-b9; (iii) for Sc contents beyond 0.5, the nanowire growth is dominated by tilted nanodomains (with a size of about 100 nm), and these nanodomains exhibit a clear cubic shape with further increasing Sc content (FIG. 1, parts b10-b11). For the ScN/GaN nanowires, regular cubic domains are directly grown on top of the GaN nanowires with a crystal size of about 50 nm. The body diagonal of the ScN cubic domains is parallel with the growth direction, i.e., c-axis (<0001>) of the GaN nanowires, which is determined by the epitaxial relationship between wz-GaN and rs-ScN, i.e., (0001)[112̅0]GaN∥(111)[11̅0]ScN. As the nanowires can be seen as strain-free for the regions far from the ScAlN/GaN interface, the clear morphology and geometry transition observed in ScAlN nanowires captured the intrinsic phase transition phenomena with increasing Sc content.

FIG. 1, part c, presents the X-ray diffraction (XRD) 2θ/ω scans of the nanowire samples shown in FIG. 1, part b. All spectra have been corrected using the diffraction peak of the Si(111) plane. The slight vibration of the GaN (0002) diffraction peaks is mainly due to the slight tilting of self-organized GaN nanowires. A clear characteristic diffraction peak in a range of 35.8-36.5° is observed for ScAlN nanowires with Sc contents up to 0.4, indicating a wurtzite crystal structure for those nanowires. However, the wurtzite phase diffraction peak degrades significantly when the Sc content increased to 0.45. Further increasing the Sc content to 0.5, a weak diffraction peak corresponding to the wurtzite phase ScAlN with lower Sc content can be detected, suggesting that a phase separation might have taken place in some regions of the nanowires. For even higher Sc contents (≥0.65), rs-phase dominated the growth, resulting in a diffraction peak close to the GaN(0002) peak. These phenomena indicate that the phase transition from wurtzite to rock-salt crystal structure happened in a Sc content range of 0.45-0.65 depending on the growth conditions and layer thickness, while the wurtzite crystal structure can be well maintained below this compositional range. The gradual transition, however, indicates that the transition is intrinsic of the ternary alloy. Considering that only the wurtzite portion contributes to the piezoelectric response and ferroelectricity of the alloy, these results indicate that the overall piezoelectricity and ferroelectricity can further be tuned in a useful way by controlling the crystal phase portions in the material.

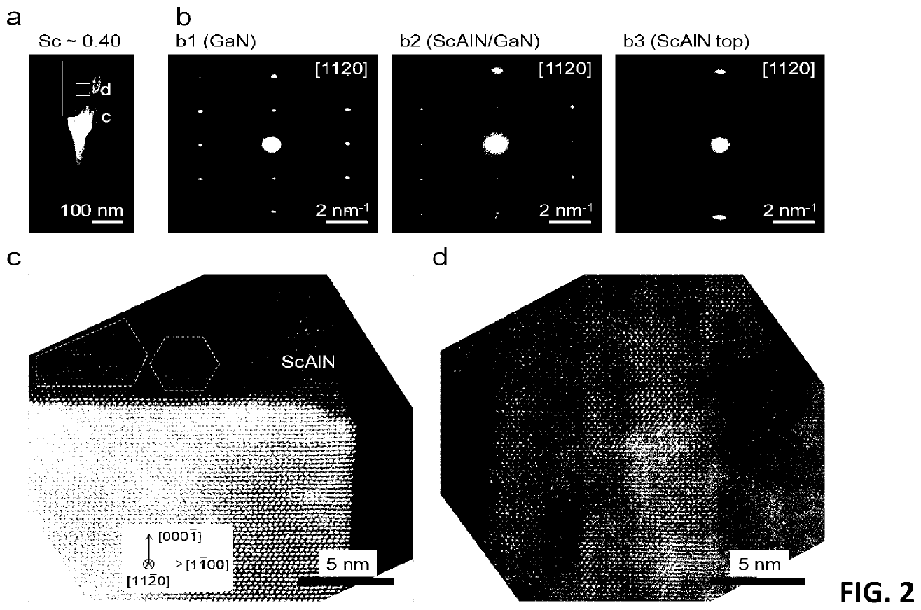

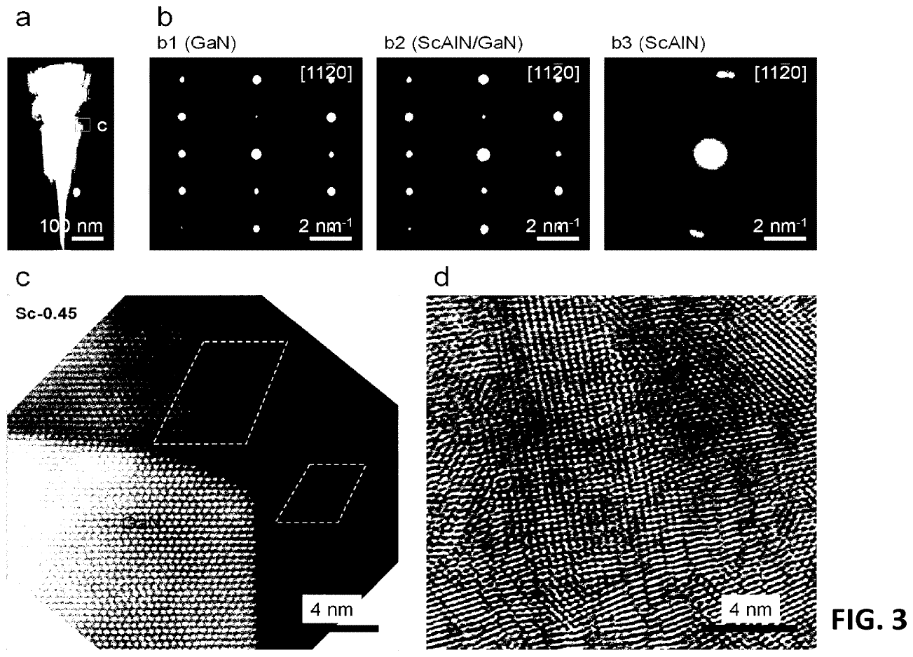

The crystal structure and phase transition of the ScAlN nanowire segments were further investigated utilizing STEM. While the microstructure of ScAlN with lower Sc contents (less than 0.4) has been previously investigated, the ScAlN nanostructures with higher Sc contents were addressed in this investigation, where a crystallographic transition from the wurtzite to the cubic is anticipated. Two representative ScAlN nanowire samples with a Sc content of about 0.40 (FIG. 1, part b8) and 0.45 (FIG. 1, part b9) were characterized, shown in FIGS. 2 and 3, respectively. For all STEM measurements, ScAlN nanowires were mechanically removed from the Si substrate and dispersed on a lacey carbon film mesh Cu TEM grid.

FIG. 2, part a, illustrates the high-angle annular dark-field STEM (HAADF-STEM) image of a single ScAlN nanowire with a Sc content of about 0.4 measured by EDS, showing a GaN nanowire template at the bottom with a 200-nm-thick ScAlN segment on top. Due to the limited diffusion ability of Sc and Al adatoms compared to Ga, the diameter for ScAlN increased compared to that of GaN. In addition, similar to spontaneously grown AlN/GaN nanowires by MBE, a thin (less than 10 nm) ScAlN shell formed along the GaN nanowires. Under optimized growth conditions, MBE-grown spontaneous III-nitride nanostructures are free of dislocations, as evidenced by the highly uniform contrast for the bottom GaN segment. However, multi-domain structure was observed in the ScAlN segment, which may be due to the low adatom mobility of Sc and Al.

To further identify the crystal phase of the structure, selective area electron diffraction (SAED) patterns were collected from the GaN, ScAlN/GaN interface, and top ScAlN regions, which are shown in FIG. 2, parts b1-b3, respectively. A single set of bright diffraction spots were observed from GaN segments (part b1), suggesting a well-defined wurtzite structure, which was confirmed by comparing the spacing ratio of the (0002) and (112̅0) plane diffraction spots to the corresponding lattice spacing ratio of ideal wurtzite GaN. The SAED pattern collected from the ScAlN/GaN interface is shown in FIG. 2, part b2. Similar regular diffraction patterns to GaN were observed, indicating that the wurtzite structure was carried over to ScAlN. By examining the image more carefully, two sets of diffraction patterns can be identified, with almost the same pattern spacing in the horizontal direction, indicating that the ScAlN layer was coherently grown on GaN near the interface region. In contrast, the top ScAlN segment shows tilted and slightly extended diffraction spots (FIG. 2, part b3), indicating non-uniform domain structure and degraded material quality, which is consistent with the columnar structure exhibited in HAADF-STEM image (FIG. 2, part d).

FIG. 2, part c, presents the high resolution HAADF-STEM captured at the ScAlN/GaN interface from the same nanowire. ScAlN was not only grown on top of the flat GaN (0001̅) surface but also on the (101̅0) side facets forming a core/shell structure. The geometry of the core/shell structure was visualized by collecting the energy dispersive spectroscopy (EDS) elemental maps along the nanowire. The underlying GaN nanowire template shows a perfect ABABAB wurtzite stacking sequence. Even though the wurtzite stacking sequence was well maintained in most ScAlN regions, a clear ABCABC stacking sequence was observed near the interface, indicating the existence of zinc blende (zb) phase ScAlN clusters (enclosed with dashed yellow circles). Because the cubic ScAlN is not the thermodynamically ground state for this Sc content (about 0.4), it may be caused by the localized accumulation of Sc adatoms during growth, which may be supported by the dense nanocrystals on the sidewall of the ScAlN nanowires. The presented STEM images are projected images of the whole atomic stacks along the zone axis, i.e., along the radial direction, thus the nanocrystals grown on the side wall of ScAlN also contributed to the observed atomic stacking sequence as well as the SAED patterns. In such a case, the observed cubic clusters are likely to come from the nanocrystals grown on the sidewall rather than a cubic domain located inside the ScAlN segment. The STEM image recorded from the ScAlN nanowire near the top surface but away from the sidewall is shown in FIG. 2, part d. Indeed, no ABCABC stacking was found. Instead, clear and sharp c-axis aligned clusters were observed, with a lateral size less than 10 nm. The fact that it is difficult to obtain a clear atomic image for all columns using the same zone axis indicates that these domains have minor in-plane rotation, agreeing well with the SAED pattern shown in FIG. 2, part b3. This kind of multi-domain structure was not observed at the ScAlN/GaN interface. The gradual relaxation of the compressive strain accumulated at the ScAlN/GaN interface may be responsible for the generation of those nano-domains.

The multi-domain structure and the nanocrystal feature became more significant with increasing Sc content to 0.45, as shown in FIG. 3, part a. Meanwhile, elongated diffraction spots are observed in the SAED pattern collected near the interface region (FIG. 3, part b2), indicating a significant distortion of the wurtzite crystal structure. In the top ScAlN region, the wurtzite-like diffraction pattern was completely substituted by circularly arranged diffraction spots, indicative of misaligned lattice without any preferred orientation. FIG. 3, part c, displays the STEM image taken at the ScAlN/GaN interface. Similarly, a few cubic ScAlN domains enclosed with dashed yellow circles appeared, which may again come from the contribution of the sidewall nanocrystals (shown in FIG. 1, part b9). Surprisingly, on the left side of the image, well-ordered wurtzite stacking of ScAlN was clearly identified in a range of at least 10 nm away from the ScAlN/GaN interface, manifesting an attractive methodology to prepare high-Sc-content, wurtzite phase ScAlN thin films, even though c-axis aligned lattice was completely absent in the top ScAlN region. Most recently, ferroelectric polarization switching has been demonstrated in nanometer thick wurtzite phase ScAlN films with lower Sc contents (less than 0.3), while the switching voltages are still high and the margin between the coercive field and breakdown field is still challenging for wurtzite ferroelectrics. In theory, the coercive field of ferroelectric ScAlN decreases with increasing Sc content under the wurtzite crystal structure framework. As such, the confined wurtzite phase with high Sc content as described herein represents a useful step toward the low voltage operation, thickness scaling down, and nanosized switching of wurtzite ferroelectrics. These examples also address the divergence between the maximum Sc contents for wurtzite phase ScAlN reported by different groups, as the strain state of the layers vary based on the deposition conditions and substrates used.

To explore the ferroelectricity of the strain-free nanowires, displacement current measurements and piezoresponse force microscopy (PFM) were used to analyze the polarization switching characteristics of an example ScAlN nanowire with a nominal Sc content of about 0.33. The length of the nanowires was extended to have a slightly merged surface to reduce the sidewall leakage after electrode formation. SiO₂ deposited by PECVD was used to define the area of the electrode and Ti/Al metal stacks were used as contacts, all of which after poling were further removed by HF for PFM measurements. SEM images of the example showed the vertical morphology of the nanowires and slightly merged surfaces.

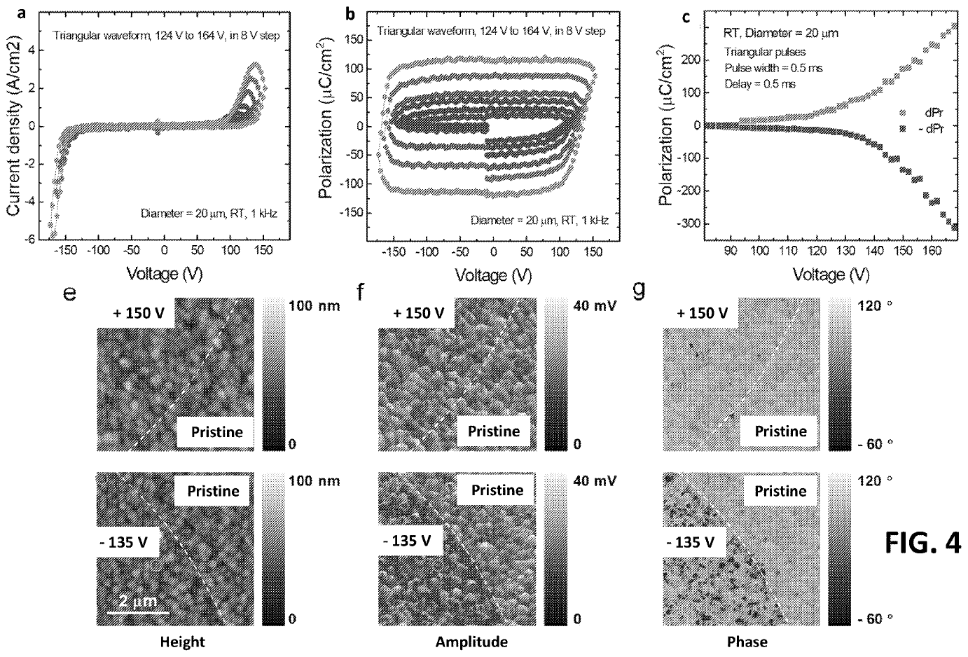

FIG. 4, part a, displays the displacement currents measured for the ScAlN nanowire example at room temperature on an electrode of 20 μm in diameter. Triangular voltage profiles were used and the leakage current was directly removed using the PUND procedure. With incremental poling voltages, increasing displacement currents were detected, corresponding to more polarization switched regions. The integral of the displacement current, which reveals the polarization that was switched, can further be found in FIG. 4, part b. Due to the non-uniformity of and possibly more leakage pathways between the nanowires, no clear saturation was observed, as shown in FIG. 4, part c. The leakage issue may be addressed through careful passivation of the nanowire surfaces. PFM measurements were further conducted to monitor and verify the polarization switching characteristics. Before PFM measurements, the capacitors were poled first, following which the top electrode and SiO₂ layer were removed using HF. FIG. 4, parts e and f, delineate the released surface morphology, amplitude contrast, and phase distribution measured by PFM after different voltage poling sequences. The white dashed curve indicates the edge between the electrode and pristine regions (which were protected by SiO₂ during poling). Interestingly, ScAlN nanowires poled by −135 V voltage pulses showed reduced amplitude contrast and reversed phase contrast, in comparison to the almost unchanged piezoelectric response for +150 V poled regions. Scattered points instead of uniform contrast in the negatively poled regions are likely a reflection of the non-uniform coercive field, either due to the length or surface variations of the nanowires. In other words, during the poling, only part of the nanowires was switched before PFM measurements. Nevertheless, the difference between the poled regions and the 180° phase separation indicates that the polarity of the nanowires has been switched, at least partially, during the electrical poling. Those results establish that the ScAlN NWs are indeed ferroelectric, rendering them the first wurtzite phase ferroelectric nanowires.

While ferroelectricity in wurtzite phase nitride films have been explored extensively recently, the demonstration of ferroelectric ScAlN nanowires has unique utility. First, ferroelectrics functioning at reduced dimensionality may be used to construct highly scaled, energy-efficient electronics. FIG. 4, part g, indicates, for the first time, that individual domains in the diameter of tens of nanometers can be switched and stabilized in wurtzite ferroelectrics. Second, for some nanowires, the entire ScAlN segment has been switched, as indicated by the red circles in FIG. 4, parts e and f. Considering the intrinsically fast strain relaxation property of the nanowires, and the minimal energy interactions between adjacent nanowires, the results imply that it is possible to intrinsically scale down the size of switchable ScAlN domains down to tens of nanometers, which is useful for a variety of device applications. The disclosed devices provide useful lateral scaling down of wurtzite ferroelectrics, thereby supporting a wide variety of compact, power-efficient electronic and piezoelectric devices.

The examples described above present the first comprehensive investigation of the crystallographic phase transition of ScAlN nanowires across the full Sc compositional range. While a gradual transition from the wurtzite to the cubic phase was observed with increasing Sc composition, it was demonstrated that a highly ordered wurtzite phase can be well-confined at the ScAlN/GaN interface, even with Sc content surpassing what can be achieved in film structures. The examples described above provide ferroelectric switching in nanometer sized ScAlN nanowires, a result that holds useful implications for device miniaturization. The successful fabrication of tunable ferroelectric ScAlN nanowires is useful for nanoscale, domain, alloy, and quantum engineering of ferroelectrics, including a variety of miniaturized devices based on wurtzite ferroelectrics.

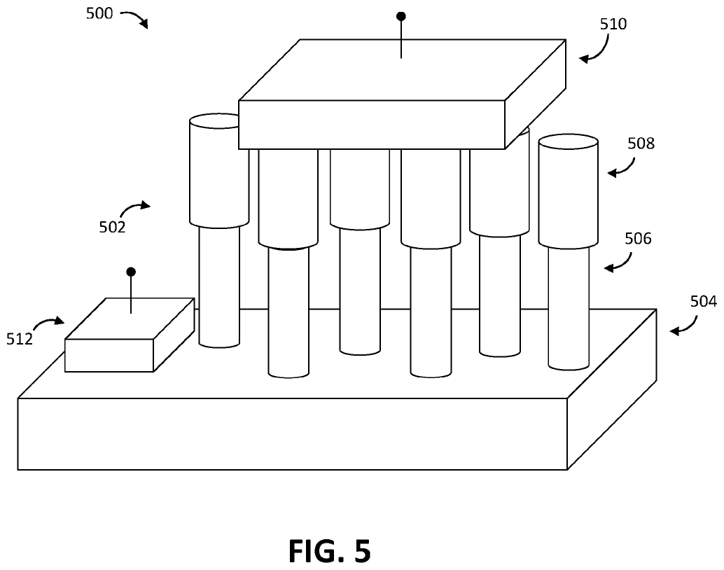

FIG. 5 shows a device 500 having an array of nanostructures 502 in accordance with one example. As described above, each nanostructure 502 of the array of nanostructures has a reduced lateral dimension to establish or maintain a wurtzite crystal structure and/or ferroelectric and/or other properties. Each nanostructure 502 may be shaped as, or otherwise include, a nanowire or other elongated structure.

The device 500 includes a substrate 504 that supports the array of nanostructures. Each nanostructure 502 of the array projects outwardly from the substrate 504 as shown. The nanostructures 502 may or may not be in contact with the substrate 504. In some cases, the substrate 504 is composed of, or otherwise includes, n-type doped silicon, but alternative or additional materials may be used, including other semiconductor materials and/or metal materials. The substrate 504 may be a uniform or composite structure.

Each nanostructure 502 of the array includes a template segment 506 or nanostructure supported by the substrate 504. The template segment 506 is composed of, or otherwise includes, a nitride semiconductor material. The nitride semiconductor material may be GaN or another III-nitride semiconductor material. The nitride semiconductor material may be doped (e.g., n-type doped) to be conductive.

The template segment 506 may have a sub-micron lateral dimension (e.g., a nanoscale diameter or other lateral dimension). In some cases, the sub-micron lateral dimension is on the order of tens of nanometers or less. However, other nanoscale lateral dimensions may be used.

Each nanostructure 502 of the array also includes a dielectric segment 508 supported by one of the template segments 506. As shown in FIG. 5, the dielectric segment 508 may be in contact with the template segment 506. In other cases, an intermediary segment may be disposed between the template and dielectric segments 506, 508. The dielectric segment 508 may be ferroelectric as described herein. The dielectric segment 508 is composed of, or otherwise includes, a nitride alloy, such as a III-nitride alloy. In some cases, the dielectric segment includes a Group IIIB element, such as Sc. As described herein, the III-nitride alloy may have a wurtzite crystal structure and a Group IIIB content of about 0.4 or higher. In the example of FIG. 5, the dielectric segment 508 is composed of ScAlN.

The dielectric segment 508 may have a sub-micron lateral dimension (e.g., a nanoscale diameter or other lateral dimension). In some cases, the sub-micron lateral dimension is on the order of tens of nanometers or less. However, other nanoscale lateral dimensions may be used.

The lateral dimension of the dielectric segment 508 may or may not be the same as the lateral dimension of the template segment 506. As described herein, in some cases, the dielectric segment 508 has a larger lateral diameter than the template segment 506.

As described herein, each nanostructure 502 of the array may further include a shell disposed along sidewalls of the template segment. The shell may be composed of, or otherwise include, the nitride alloy. For instance, the shell may have the same material composition as the dielectric segment.

The device 500 further includes a number of contacts. A contact may be provided for each electrode of the device. In the example of FIG. 5, the device 500 includes an upper contact pad 510 and a lower contact pad 512 for upper and lower electrodes, respectively. Each contact pad 510, 512 may include a metal stack having any number of metal layers. For instance, the stack may be or include a Ti/Al metal stack.

The device 500 may include additional, alternative or fewer components or elements. For instance, the device 500 may include one or more passivation layers.

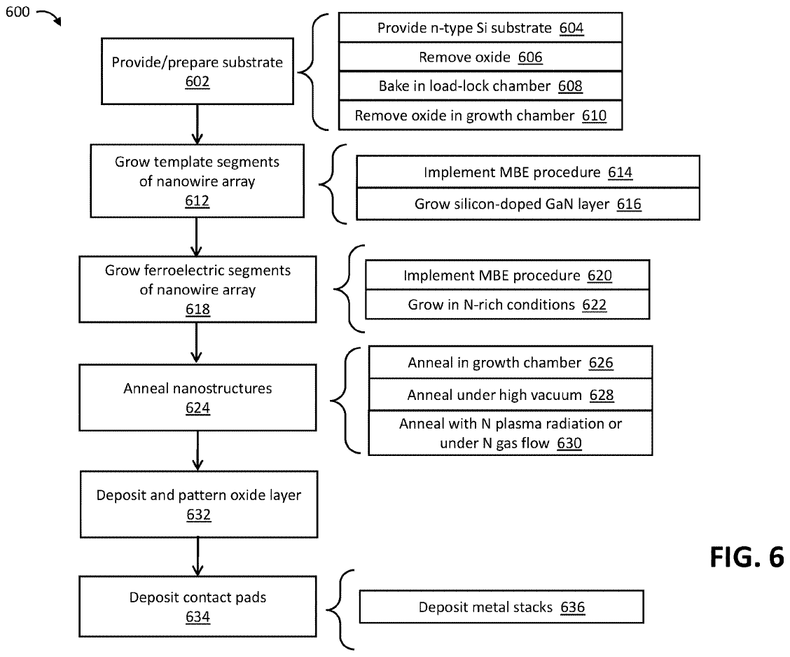

FIG. 6 shows a method 600 of fabricating a device having an array of nanostructures in accordance with one example. The method 600 may be used to fabricate the device 500 of FIG. 5 or other devices.

The method 600 includes an act 602 in which a substrate is provided. The act 602 may include providing an n-type Si substrate as described herein in an act 604, but alternative substrates may be used. An etch and/or other procedure may be implemented in an act 606 to remove an oxide layer. As described herein, the substrate may be baked in an MBE load-lock chamber in an act 608. A native oxide may also be removed in an act 610 when the substrate is moved to the growth chamber.

The method 600 includes an act 612 in which template segments or nanostructures are grown via implementation of a growth procedure. The template segments may be grown on the substrate. The act 612 may include implementation of an MBE procedure in an act 614. Other procedures may be used as described herein. In some cases, the growth procedure of the act 612 may be configured to dope the template nanostructures such that each template nanostructure is conductive. For instance, a silicon-doped GaN layer is grown in an act 616. Alternative or additional segments or layers may be grown. In some cases, the template segments are grown in N-rich conditions.

The method 600 includes an act 618 in which another growth procedure is implemented to grow dielectric (e.g., ferroelectric) segments or nanostructures supported by the template nanostructures. The dielectric segments may be grown on the template segments. Each dielectric segment may be composed of, or otherwise include, a nitride alloy (e.g., a III-nitride alloy), as described herein. In some cases, the growth procedure of the act 618 is configured such that each dielectric segment has a Group IIIB content of about 0.4 or higher The act 618 may include implementation of an MBE procedure in an act 620, but other procedures may be used as described herein. In some cases, the dielectric segments are grown in N-rich conditions in an act 622. The growth procedure of the act 618 may be configured such that a shell grows along sidewalls of the template nanostructures. The shell may be composed of, or otherwise include, the III-nitride alloy, as described herein.

The growth procedures are configured such that the template and dielectric nanostructures have a sub-micron lateral dimension. The template and dielectric nanostructures may or may not have the same lateral dimension. For instance, the growth procedures may be configured such that the dielectric nanostructure has a larger lateral diameter than the template nanostructure, as described herein.

The nanostructures may or may not be annealed in an act 624. The anneal procedure may be implemented in an act 626 in the same growth chamber in which the nanostructures are grown. The anneal procedure may be implemented under high vacuum in an act 628. Alternatively or additionally, the anneal procedure may include an act 630 in which the nanostructures are annealed with N plasma radiation or under N gas flow.

The method 600 may include an act 632 in which an oxide layer is deposited and patterned. In the example of FIG. 6, the oxide layer is patterned to support the formation of contact pads deposited in an act 634. In some cases, the act 634 includes an act 636 in which a number of metal layers are deposited to form metal stacks.

The method 600 may include additional, alternative, or fewer acts. For instance, the method 600 may include one or more acts directed to passivation.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a nanostructure supported by the substrate, the nanostructure comprising:
a template segment supported by the substrate, the template segment comprising a nitride semiconductor material; and
a ferroelectric segment supported by the template segment, the ferroelectric segment comprising a nitride alloy;
wherein the ferroelectric segment has a sub-micron lateral dimension.

2. The device of claim 1, wherein the ferroelectric segment has a wurtzite crystal structure.

3. The device of claim 1, wherein the nitride alloy has a Group IIIB content of about 0.4 or higher.

4. The device of claim 1, wherein the nanostructure is configured as a nanowire.

5. The device of claim 1, wherein the sub-micron lateral dimension is on the order of tens of nanometers or less.

6. The device of claim 1, wherein the ferroelectric segment has a nanoscale lateral dimension.

7. The device of claim 1, wherein the ferroelectric segment has a larger lateral diameter than the template segment.

8. The device of claim 1, wherein the nanostructure further comprises a shell disposed along sidewalls of the template segment, the shell comprising the nitride alloy.

9. The device of claim 1, wherein the ferroelectric segment is in contact with the template segment.

10. The device of claim 1, wherein the nanostructure is one of an array of nanostructures of the device, each nanostructure of the array of nanostructures projecting outward from the substrate.

11. The device of claim 1, wherein:
the nitride semiconductor material is a III-nitride semiconductor material;
the nitride alloy is a III-nitride alloy; and
the nitride alloy comprises a Group IIIB element.

12. A device comprising:
a substrate; and
a nanostructure supported by the substrate, the nanostructure comprising:
a template segment supported by the substrate, the template segment comprising a III-nitride semiconductor material; and
a dielectric segment supported by the template segment, the dielectric segment comprising a III-nitride alloy, the III-nitride alloy comprising a Group IIIB element;
wherein the III-nitride alloy has a wurtzite crystal structure.

13. The device of claim 12, wherein the III-nitride alloy has a Group IIIB content of about 0.4 or higher.

14. The device of claim 12, wherein the dielectric segment is ferroelectric.

15. The device of claim 12, wherein the nanostructure is configured as a nanowire.

16. The device of claim 12, wherein the dielectric segment has a sub-micron lateral dimension.

17. The device of claim 12, wherein the dielectric segment has a lateral dimension on the order of tens of nanometers or less.

18. The device of claim 12, wherein the dielectric segment has a larger lateral diameter than the template segment.

19. The device of claim 12, wherein the nanostructure further comprises a shell disposed along sidewalls of the template segment, the shell comprising the III-nitride alloy.

20. The device of claim 12, wherein the dielectric segment is in contact with the template segment.

21. The device of claim 12, wherein the nanostructure is one of an array of nanostructures of the device, each nanostructure of the array of nanostructures projecting outward from the substrate.

22. A method for fabricating a device, the method comprising:
providing a substrate;
implementing a first growth procedure to grow a template nanostructure supported by the substrate, the template segment comprising a nitride semiconductor material; and
implementing a second growth procedure to grow a ferroelectric nanostructure supported by the template nanostructure;
wherein the first growth procedure and the second growth procedure are configured such that the template nanostructure has a sub-micron lateral dimension and the ferroelectric nanostructure has a sub-micron lateral dimension, respectively.

23. The method of claim 22, wherein providing the substrate comprises removing a native oxide layer while the substrate is disposed in a growth chamber in which the first and second growth procedures are implemented.

24. The method of claim 22, wherein the first growth procedure is configured to dope the nitride semiconductor material such that the template nanostructure is conductive.

25. The method of claim 22, wherein the second growth procedure is configured such that the nitride alloy has a Group IIIB content of about 0.4 or higher.

26. The method of claim 22, wherein the first growth procedure is configured such that the template nanostructure has a lateral dimension on the order of tens of nanometers or less.

27. The method of claim 22, wherein the first and second growth procedures are configured such that the ferroelectric nanostructure has a larger lateral diameter than the template nanostructure.

28. The method of claim 22, wherein the second growth procedure is configured such that a shell grows along sidewalls of the template nanostructure, the shell comprising the III-nitride alloy.

29. The method of claim 22, wherein:
the nitride semiconductor material is a III-nitride semiconductor material;
the ferroelectric nanostructure comprises a III-nitride alloy; and
the III-nitride alloy comprises a Group IIIB element.

30. A method for fabricating a device, the method comprising:
providing a substrate;
implementing a first growth procedure to grow a template nanostructure supported by the substrate, the template segment comprising a III-nitride semiconductor material; and
implementing a second growth procedure to grow a dielectric nanostructure supported by the template nanostructure, the dielectric nanostructure comprising a III-nitride alloy, the III-nitride alloy comprising a Group IIIB element;
wherein the second growth procedure is configured such that the III-nitride alloy has a wurtzite crystal structure.

31. The method of claim 30, wherein the second growth procedure is configured such that the III-nitride alloy has a Group IIIB content of about 0.4 or higher.

32. The method of claim 30, wherein the first growth procedure is configured to dope the III-nitride semiconductor material such that the template nanostructure is conductive.

33. The method of claim 30, wherein the first growth procedure and the second growth procedure are configured such that the template nanostructure has a sub-micron lateral dimension and the dielectric nanostructure has a sub-micron lateral dimension, respectively.

34. The method of claim 30, wherein the first growth procedure is configured such that the template nanostructure has a lateral dimension on the order of tens of nanometers or less.

35. The method of claim 30, wherein the first and second growth procedures are configured such that the dielectric nanostructure has a larger lateral diameter than the template nanostructure.

36. The method of claim 30, wherein the second growth procedure is configured such that a shell grows along sidewalls of the template nanostructure, the shell comprising the III-nitride alloy.

37. A device comprising:
a substrate; and
a ferroelectric nanostructure supported by the substrate, the ferroelectric nanostructure comprising a nitride alloy;
wherein the ferroelectric nanostructure has a sub-micron lateral dimension.

38. A method of fabricating a device, the method comprising:
providing a substrate; and
implementing a growth procedure to grow a ferroelectric nanostructure supported by the substrate;
wherein the growth procedure is configured such that the ferroelectric nanostructure has a sub-micron lateral dimension.
